(19) United States
(12) Patent Application Publication
(10) Pub. No.: US 2026/0334110 A1
(43) Pub. Date: Oct. 22, 2026

(54) METHOD AND SYSTEM FOR IN-SITU ETCHING AND DEPOSITING A MATERIAL

(71) Applicant: ASM IP Holding B.V., Almere (NL)

(72) Inventors: João Ricardo Antunes Afonso, Tokyo (JP); Hideaki Fukuda, Tokyo (JP); Shun-Hong Li, Hsinchu City (TW); Kai Okabe, Kawasaki-shi (JP)

(21) Appl. No.: 19/639,531

(22) Filed: Apr. 6, 2026

Related U.S. Application Data
(60) Provisional application No. 63/785,894, filed on Apr. 9, 2025.

(51) Int. Cl. H10P 14/60; H10P 50/28

(52) U.S. Cl. CPC H10P 14/668; H10P 14/6336; H10P 50/285

(57) ABSTRACT

Methods for forming a material on a surface of the substrate are provided. The methods comprise the steps of providing a substrate within a reaction chamber, the substrate comprising a second material; conformally depositing a layer of first material onto the substrate; selectively etching at least part of the first material; and conformally depositing a second layer of first material. The steps of depositing the first material and the step of selectively etching the first material are performed in the same reaction chamber.

### CROSS-REFERENCE TO RELATED APPLICATIONS

This application claims priority to U.S. Provisional Patent Application Ser. No. 63/785,894 filed Apr. 9, 2025 and titled METHOD AND SYSTEM FOR IN-SITU ETCHING AND DEPOSITING A MATERIAL, the disclosure of which is hereby incorporated by reference in its entirety.

### FIELD OF INVENTION

The present disclosure pertains to semiconductor manufacturing technologies, specifically to methods for enhancing etching selectivity and gapfill quality in thin film deposition processes.

### BACKGROUND OF THE DISCLOSURE

In the field of semiconductor manufacturing, the processes for creating precise and reliable microstructures are of great importance. Techniques for depositing thin films with high uniformity and conformality are widely used. However, challenges arise in achieving selective material removal between the deposited film and underlying materials, which can impact the quality and performance of the final product. Existing methods often struggle with selectivity, leading to undesirable effects such as excessive removal or damage to the underlying layers. These limitations necessitate innovative approaches to enhance selectivity and improve the overall process.

Furthermore, the formation of seams during material deposition poses significant challenges in maintaining the integrity of the microstructures through subsequent processing steps. Current solutions may not adequately address seam formation, resulting in compromised quality and potential defects in the final product. There is a pressing need for a streamlined method to create a layer that can withstand rigorous processing conditions, ensuring the reliability and performance of semiconductor devices.

### SUMMARY OF THE DISCLOSURE

Various embodiments of the present disclosure relate to method of depositing material onto a surface of a substrate—e.g., depositing material over features on the substrate surface—that are suitable for filling gaps on the surface of the substrate. While the ways in which various embodiments of the present disclosure address drawbacks of prior method and systems are discussed in more detail below, in general, various embodiments of the disclosure provide improved methods suitable for filling the gaps on the surface.

Other embodiments of the present disclosure relate to method of etching a material from the surface of a substrate that comprises gaps. In one embodiment, the disclosure includes a method for etching a material, comprising providing a substrate comprising a deposited first material into a reaction chamber; providing a reactive species generated from a plasma produced from an etching reactant gas into the reaction chamber to etch the first material. The plasma is pulsed plasma, and the plasma is selected from at least one of high-density plasma, microwave plasma, or inductively coupled plasma. In some embodiments, the etching is spontaneous etching, and the etching reactant is selected from the list consisting of NF₃, CF₄, C₂F₆, SF₆, NH₂F, C₃F₈, F₂, XeF₂, HF, CHF₃, CH₃F, CH₂F₂, C₄F₈, C₄F₆, Cl₂, SiCl₄, BCl₃, C₄F₆, NH₃, N₂H₂ and any combinations thereof.

In a further embodiments, the disclosure includes a method for depositing a material on a substrate. The method comprises providing a substrate into a reaction chamber, the substrate comprising a second material; conformally depositing a first material onto the substrate; selectively etching at least part of the first material; and conformally depositing third or first material onto the substrate, wherein the steps of depositing the first and third materials and the step of selectively etching the first material are performed in the same reaction chamber. In some embodiments, the step of selectively etching comprises removing the first material, and not removing or substantially not removing any of the second material. The step of selectively etching is performed by a method according to the etching method described above.

In some embodiments, the substrate comprises at least one gap having a proximal surface, sidewalls, and a distal surface, and the first material is conformally deposited into the at least one gap to fill the gap, so that the deposited first material covers the proximal surface, the sidewalls, and the distal surface.

In some embodiments, during the step of selectively etching at least part of the first material, the first material is etched so that the gap is partially filled. In some embodiments, the second material comprises silicon oxide, and the first material comprises boron nitride. In some embodiments, the third material comprises silicon nitride.

In a further embodiments, the method comprises etching the third or first material so that substantially no material covers the proximal surface of the gap.

In yet another embodiment, the first material is conformally deposited by executing at least one deposition cycle, wherein the at least one deposition cycle comprises providing a silicon precursor into the reaction chamber in vapor phase; and providing a reactive species generated from a plasma produced from a nitrogen-containing gas into the reaction chamber. The boron precursor comprises one or more of boron halide, borane, borazine and organoborane. In some embodiments, the boron precursor comprises the boron halide selected from list consisting of boron triiodide, boron tribromide, boron trichloride, diboron tetrachloride, boron monofluoride, boron trifluoride and diboron tetrafluoride. In some embodiments, the boron precursor comprises borane selected from borane, diborane, tetraborane, pentaborane, decaborane and borane-ammonia complex. In some embodiments, the boron precursor comprises borazine or substituted borazine. In some embodiments, the boron precursor comprises organoborane selected from the list consisting of trimethylborane, triethylborane 3-tris-(dimethylamino) borane, dimethylamine borane and triethylamine borane. In some embodiments, the nitrogen-containing gas comprises one or more of nitrogen (N₂), N₂O, and NO.

In a third aspect, the disclosure includes a system for depositing a material on a surface of a substrate, the system comprising a reaction chamber for accommodating a substrate comprising a gap and a second material; a boron precursor source in fluid communication via a first valve with the reaction chamber; a nitrogen reactant source in fluid communication via a second valve with the reaction chamber; an etching reactant source in fluid communication via a third valve with the reaction chamber; and a controller operably connected to the first valve, the second valve, and the third valve, and configured and programmed to control: supplying a boron precursor into the reaction chamber; supplying a nitrogen reactant into the reaction chamber; supplying an etchant into the reaction chamber; and depositing a material on the surface of the substrate with the method for depositing a material on a substrate as described above. These and other features will be more clearly understood from the following detailed description taken in conjunction with the accompanying drawings and claims.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 illustrates a method in accordance with at least one embodiment of the disclosure.

FIG. 2 illustrates a system in accordance with at least one embodiment of the disclosure.

FIG. 3 illustrated a method in accordance with at least one embodiment of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

A vapor deposition method according to the current disclosure means processes in which material is deposited on the substrate from gas phase.

Generally, in cyclic deposition processes according to the current disclosure, such as atomic layer deposition (ALD) and molecular layer deposition (MLD), during each cycle, a precursor is introduced to a reaction chamber and is chemisorbed to a substrate surface (e.g., a substrate surface that may include a previously deposited material from a previous deposition cycle or other material). In some embodiments, the precursor on the substrate surface does not readily react with additional precursor (i.e., the deposition of the precursor may be a partially or fully self-limiting reaction). Thereafter, a reactant may be introduced into the reaction chamber for use in converting the chemisorbed precursor to the desired material on the deposition surface. The reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber. Thus, in some embodiments, the cyclic deposition process comprises purging the reaction chamber after providing a precursor into the reaction chamber. In some embodiments, the cyclic deposition process comprises purging the reaction chamber after providing a precursor into the reaction chamber. In some embodiments, the cyclic deposition process comprises purging the reaction chamber after providing a reactant precursor into the reaction chamber. In some embodiments, the cyclic deposition process comprises purging the reaction chamber after providing a precursor into the reaction chamber, and after providing reactant into the reaction chamber into the reaction chamber. Without limiting the current disclosure to any specific theory, ALD and MLD may be similar processes in terms of self-limiting reactions and slower and more controllable layer growth speed compared to CVD. Generally, ALD is used to deposit inorganic materials, whereas in MLD, the precursors may be fully organic molecules.

The process may comprise one or more cyclic phases. In some embodiments, the process comprises or one or more acyclic (i.e. continuous) phases. In some embodiments, the deposition process comprises the continuous flow of at least one precursor. In such an embodiment, the process comprises a continuous flow of a precursor or reactant. In some embodiments, one or more of the precursors/reactants are provided in the reaction chamber continuously.

In some embodiments, at least one of precursor and reactant is provided to the reaction chamber in pulses. In some embodiments, the precursor is supplied in pulses and the reactant is supplied in pulses, and the reaction chamber is purged between consecutive pulses of precursor and reactant. A duration of providing precursor and/or a reactant into the reaction chamber (i.e. silicon precursor pulse time and nitrogen-containing reactant pulse time, respectively) may be, for example, from about 0.01 s to about 60 s, for example from about 0.01 s to about 5 s, or from about 1 s to about 20 s, or from about 0.5 s to about 10 s, or from about 5 s to about 15 s, or from about 10 s to about 30 s, or from about 10 s to about 60 s, or from about 20 s to about 60 s. The duration of first precursor or a second precursor pulse may be, for example 0.03 s, 0.1 s, 0.5 s, 1 s, 1.5 s, 2 s, 2.5 s, 3 s, 4 s, 5 s, 8 s, 10 s, 12 s, 15 s, 25 s, 30 s, 40 s, 50 s or 60 s. In some embodiments, first precursor pulse time may be at least 5 seconds, or at least 10 seconds. In some embodiments, first precursor pulse time may be at most 5 seconds, or at most 10 seconds or at most 20 seconds, or at most 30 seconds. In some embodiments, second precursor pulse time may be at least 5 seconds, or at least 10 seconds, or at least 20 seconds. In some embodiments, second precursor pulse time may be at most 5 seconds, or at most 10 seconds or at most 20 seconds, or at most 30 seconds.

The pulse times for precursor, and reactant vary independently according to process in question. The selection of an appropriate pulse time may depend on the substrate topology. For higher aspect ratio structures, longer pulse times may be needed to obtain sufficient surface saturation in different areas of a high aspect ratio structure. Also the selected precursor and reactant chemistries may influence suitable pulsing times. For process optimization purposes, shorter pulse times might be preferred as long as appropriate layer properties can be achieved. In some embodiments, precursor pulse time is longer than reactant pulse time. In some embodiments, reactant pulse time is longer than precursor pulse time. In some embodiments, precursor pulse time is the same as reactant pulse time.

In some embodiments, providing precursor and/or a reactant into the reaction chamber comprises pulsing the precursor and the reactant over a substrate. In certain embodiments, pulse times in the range of several minutes may be used for the precursor and/or the reactant. In some embodiments, precursor may be pulsed more than one time, for example two, three, four or five times, before a reactant is pulsed to the reaction chamber. Similarly, there may be more than one pulse, such as two, three or four pulses, of a reactant before precursor is pulsed (i.e. provided) into the reaction chamber.

As used herein, the term “purge” refers to a procedure in which vapor phase precursors and/or vapor phase byproducts are removed from the substrate surface for example by evacuating the reaction chamber with a vacuum pump and/or by replacing the gas inside a reaction chamber with an inert or substantially inert gas such as argon or nitrogen. Purging may be effected between two pulses of gases which react with each other. However, purging may be effected between two pulses of gases that do not react with each other. For example, a purge, or purging may be provided between pulses of two precursors or between a precursor and a reactant. Purging may avoid or at least reduce gas-phase interactions between the two gases reacting with each other. It shall be understood that a purge can be effected either in time or in space, or both. For example in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example in the case of spatial purges, a purge step can take the following form: moving a substrate from a first location to which a first precursor is continually supplied, through a purge gas curtain or another means of separating the two spaces, to a second location to which a second precursor is continually supplied. Purging times may be, for example, from about 0.01 seconds to about 20 seconds, from about 0.05 s to about 20 s, or from about 1 s to about 20 s, or from about 0.5 s to about 10 s, or between about 1 s and about 7 seconds, such as 5 s, 6 s or 8 s. However, other purge times can be utilized if necessary, such as where highly conformal step coverage over extremely high aspect ratio structures or other structures with complex surface morphology is needed, or in specific reactor types, such as a batch reactor, may be used.

As used herein, the term “layer” and/or “film” can refer to any continuous or non-continuous material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. In some embodiments, a layer according to the current disclosure is substantially continuous.

In this disclosure, “gas” can include material that is a gas at normal temperature and pressure (NTP), a vaporized solid and/or a vaporized liquid, and can be constituted by a single gas or a mixture of gases, depending on the context. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction space, and can include a seal gas.

The terms “precursor” and “reactant” can refer to molecules (compounds or molecules comprising a single element) that participate in a chemical reaction that produces another compound or an element. A precursor typically contains portions that are at least partly incorporated into the compound or element resulting from the chemical reaction in question. Such a resulting compound or element may be deposited on a substrate. In some instances, a reactant is a precursor. In other instances, the compound or element that results from the chemical reaction does not contain a portion of the reactant (an element or group within the reactant) and therefore the reactant is not a precursor.

In some embodiments, a precursor or a reactant is provided in a mixture of two or more compounds. In a mixture, the other compounds in addition to the precursor may be inert compounds or elements. In some embodiments, a precursor or a reactant is provided in a composition. Composition may be a solution or a gas in standard conditions.

The method of depositing material according to the current disclosure comprises providing a substrate in a reaction chamber. In other words, a substrate is in a space where the deposition conditions can be controlled. The reaction chamber may be a single wafer reactor. Alternatively, the reaction chamber may be a batch reactor. The reaction chamber can form part of a vapor processing assembly for manufacturing semiconductor devices. The processing assembly may comprise one or more multi-station processing chambers. In some embodiments, the substrate is moved between processing stations of a multi-station processing chamber. The reaction chamber may be part of a cluster tool in which different processes are performed to form an integrated circuit. Various phases of method can be performed within a single reaction chamber, or they can be performed in multiple reaction chambers, such as reaction chambers of a cluster tool, or deposition stations of a multi-station processing chamber.

In some embodiments, the reaction chamber may be a flow-type reactor, such as a cross-flow reactor. In some embodiments, the reaction chamber may be a showerhead reactor. In some embodiments, the reaction chamber may be a hot-wall reactor. In some embodiments, the reaction chamber may be a space-divided reactor. In some embodiments, the reaction chamber may be single wafer ALD reactor. In some embodiments, the reaction chamber may be a high-volume manufacturing single wafer ALD reactor. In some embodiments, the reaction chamber may be a batch reactor for manufacturing multiple substrates simultaneously.

The reaction chamber can form part of an atomic layer deposition (ALD) assembly. The reaction chamber can form part of a chemical vapor deposition (CVD) assembly.

As used herein, the term “comprising” indicates that certain features are included, but that it does not exclude the presence of other features, as long as they do not render the claim unworkable. In some embodiments, the term “comprising” includes “consisting.”

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. Likewise, when the term “consisting essentially” is used referring to a chemical compound, substance, or composition of matter, it indicates that the chemical compound, substance, or composition of matter contains the components which are listed but can also containing trace elements and/or impurities that do not materially affect the characteristics of said chemical compound, substrate, or composition of matter. This notwithstanding, the chemical compound, substance, or composition of matter may, in some embodiments, comprise other components as trace elements or impurities, apart from the components that are listed.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

The term “substantially” as applied to a composition, a method, or a system generally refers to a proportion of a value, a property, a characteristic, or the like, or conversely a lack thereof, that is at least about 70%, at least about 80%, at least about 90%, at least about 95%, at least about 97%, at least about 98%, at least about 99%, at least about 99.5%, at least about 99.9%, or more, or any proportion between about 70% and about 100%. In some embodiments, the term “substantially” means a proportion of about 90%, about 95%, about 97%, about 98%, about 99%, about 99.5%, or about 99.9%.

The term “essentially” as applied to a composition, a method, or a system generally means that the additional components do not substantially modify the properties and/or function of the composition, the method, or the system.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X1-Xn, Y1-Ym, and Z1-Zo, the phrase is intended to refer to a single element selected from X, Y, and Z, a combination of elements selected from the same class (e.g., X1 and X2) as well as a combination of elements selected from two or more classes (e.g., Y1 and Zo).

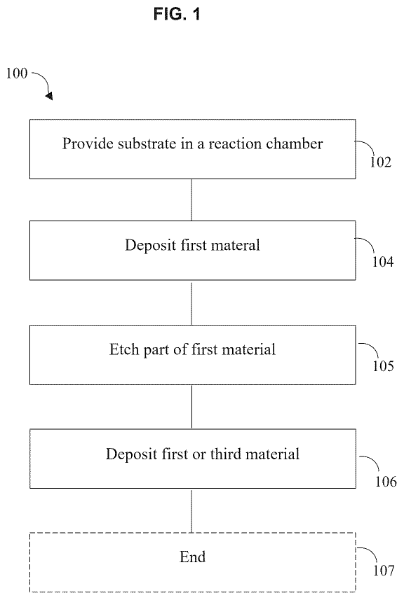

Turning now to the figures, FIG. 1 illustrates a method 100 in accordance with exemplary embodiments of the disclosure. In the illustrated example, method 100 includes the steps of providing a substrate within a reaction chamber (102), depositing a first material (104), etching part of the first material (105) and depositing a first or third material (106), and ending the process (107).

In step 102 a substrate is provided into the reaction chamber. The reaction chamber used during step 102 can be or include a reaction chamber of a chemical vapor deposition reactor system configured to perform a deposition process. The deposition process may be a chemical vapor deposition process and/or a cyclical deposition process. The reaction chamber can be a standalone reaction chamber or part of a cluster tool. The reaction chamber may be a batch processing tool. In some embodiments, a flow-type reactor may be utilized. In some embodiments, a showerhead-type reactor may be utilized. In some embodiments, a space divided reactor may be utilized. In some embodiments, a high-volume manufacturing-capable single wafer reactor may be utilized. In other embodiments, a batch reactor comprising multiple substrates may be utilized. For embodiments in which a batch reactor is used, the number of substrates may be in the range of 10 to 200, or 50 to 150, or even 100 to 130. The reactor can be configured as a thermal reactor—with no plasma excitation apparatus. Alternatively, the reactor can include direct and/or remote plasma apparatus.

In some embodiments, if desired, the exposed surfaces of the substrate may be pretreated to provide reactive sites. In some embodiments, a separate pretreatment step is not required. In some embodiments, the substrate is pretreated to provide a desired surface termination, for example, by exposing the substrate surface to a pretreatment plasma.

In some embodiments of the disclosure, the substrate disposed within the reaction chamber may be heated to a desired deposition temperature for a subsequent deposition. For example, the substrate may be heated to a substrate temperature of less than approximately 600° C., less than approximately 500° C., or less than approximately 450° C., or less than approximately 400° C., or less than approximately 350° C., or less than approximately 300° C., or less than approximately 250° C., or even less than approximately 200° C. In some embodiments of the disclosure, the substrate temperature during step 102 may be greater than room temperature, between approximately 300° C. and approximately 600° C., or approximately 350° C. and approximately 550° C., or approximately 200° C. and approximately 400° C. The lower temperatures may be preferred for plasma-assisted processes, while the higher temperatures may be desired for thermal deposition processes. The temperature during steps 104, 105 and/or 106 can also be within these ranges.

In addition to controlling the temperature of the substrate, the pressure in the reaction chamber may also be regulated to enable deposition of desired boron nitride. In some embodiments, the boron nitride comprises hexagonal boron nitride. In some embodiments, the boron nitride comprises amorphous boron nitride. In some embodiments, a pressure can be controlled between about 0.5 Torr and about 50 Torr (e.g., for thermal processes) or about 1 Torr and about 10 Torr (e.g., for plasma-enhanced processes). The pressure during steps 104, 105 and/or 106 can also be within these ranges.

Once the temperature of substrate has been set to the desired deposition temperature and pressure in the reaction chamber has been regulated as desired, method 100 may continue to step 104. During step 104 a first material is deposited onto the substrate. Step 104 may be divided into two sub-steps, a first sub-step of providing a boron precursor into the reaction chamber and a second sub-step of contacting the substrate with a reactive species generated from a plasma produced from a nitrogen-containing gas. When the step 104 includes a cyclical process, the first and second sub-steps can be performed sequentially with an intervening purge step between them. When the step 104 includes a CVD process, the first and second sub-steps can overlap. In the first sub-set, a boron precursor is provided into the reaction chamber in vapor phase. In the case of cyclical deposition, the boron precursor can be pulsed to the reaction chamber. In accordance with some embodiments, the boron precursor may be supplied to the reaction chamber with some carrier gas flow. In some embodiments, the boron precursor may comprise a volatile silicon species that is reactive with the surface of the substrate. The boron precursor pulse may self-saturate the substrate surface such that excess constituents of the boron precursor pulse do not further react with the molecular layer formed by this process.

The boron precursor pulse is preferably supplied as a vapor phase reactant. The boron precursor gas may be considered “volatile” for the purposes of the present disclosure if the species exhibits sufficient vapor pressure under the process conditions to transport species to the substrate surface in sufficient concentration to saturate the exposed surfaces.

In some embodiments, the vapor phase boron precursor comprises one or more of boron halide, borane, borazine and organoborane. In some embodiments, the boron precursor comprises the boron halide selected from list consisting of boron triiodide, boron tribromide, boron trichloride, diboron tetrachloride, boron monofluoride, boron trifluoride and diboron tetrafluoride.

In some embodiments, the boron precursor comprises borane selected from borane, diborane, tetraborane, pentaborane, decaborane and borane-ammonia complex. In some embodiments, the vapor phase boron precursor comprises boron and hydrogen. In some embodiments, the boron precursor comprises borane, diborane, tetraborane, pentaborane, decaborane and borane-ammonia complex.

In some particular embodiments, the method as disclosed herein may provide that the boron precursor is represented by the following general formula (I)

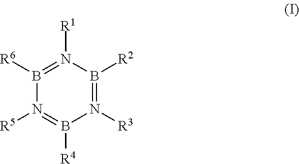

wherein R¹, R², R³, R⁴, R⁵, R⁶ are each independently selected from the group consisting of hydrogen, halogen, alkyl, alkenyl, and alkoxy.

The term “halo” or “halogen” as a group or part of a group is generic for fluoro (F), chloro (Cl), bromo (Br), iodo (I).

The term “alkyl” as a group or part of a group, refers to a hydrocarbyl group of formula CₙH₂ₙ₊₁ wherein n is a number greater than or equal to 1. Alkyl groups may be linear or branched and may be substituted as indicated herein. Generally, alkyl groups of this disclosure comprise from 1 to 20 carbon atoms, preferably from 1 to 10 carbon atoms, preferably from 1 to 8 carbon atoms, preferably from 1 to 6 carbon atoms, more preferably from 1 to 4 carbon atoms. When a subscript is used herein following a carbon atom, the subscript refers to the number of carbon atoms that the named group may contain. For example, the term “C1-20alkyl”, as a group or part of a group, refers to a hydrocarbyl group of formula CₙH₂ₙ₊₁ wherein n is a number ranging from 1 to 20. Thus, for example, “C1-8alkyl” includes all linear or branched alkyl groups with between 1 and 8 carbon atoms, and thus includes methyl, ethyl, n-propyl, i-propyl, butyl, and its isomers (e.g., n-butyl, i-butyl, and t-butyl); pentyl and its isomers, hexyl, and its isomers, etc. A “substituted alkyl” refers to an alkyl group substituted with one or more substituent(s) (for example 1 to 3 substituent(s), for example 1, 2, or 3 substituent(s)) at any available point of attachment.

When the suffix “ene” is used in conjunction with an alkyl group, i.e., “alkylene,” this is intended to mean the alkyl group as defined herein having two single bonds as points of attachment to other groups. As used herein, the term “alkylene” also referred as “alkanediyl,” by itself or as part of another substituent, refers to alkyl groups that are divalent, i.e., with two single bonds for attachment to two other groups. Alkylene groups may be linear or branched and may be substituted as indicated herein. Non-limiting examples of alkylene groups include methylene (—CH₂—), ethylene (—CH₂—CH₂—), methylmethylene (—CH(CH₃)—), 1-methyl-ethylene (—CH(CH₃)—CH₂—), n-propylene (—CH₂—CH₂—CH₂—), 2-methylpropylene (—CH₂—CH(CH₃)—CH₂—), 3-methylpropylene (—CH₂—CH₂—CH(CH₃)—), n-butylene (—CH₂—CH₂—CH₂—CH₂—), 2-methylbutylene (—CH₂—CH(CH₃)—CH₂—CH₂—), 4-methylbutylene (—CH₂—CH₂—CH₂—CH(CH₃)—), pentylene and its chain isomers, hexylene and its chain isomers.

The term “alkenyl” as a group or part of a group, refers to an unsaturated hydrocarbyl group, which may be linear, or branched, comprising one or more carbon-carbon double bonds. Generally, alkenyl groups of this disclosure comprise from 3 to 20 carbon atoms, preferably from 3 to 10 carbon atoms, preferably from 3 to 8 carbon atoms. When a subscript is used herein following a carbon atom, the subscript refers to the number of carbon atoms that the named group may contain. Examples of C3 20alkenyl groups are ethenyl, 2-propenyl, 2-butenyl, 3-butenyl, 2-pentenyl and its isomers, 2-hexenyl and its isomers, 2,4-pentadienyl, and the like.

The term “alkoxy” or “alkyloxy,” as a group or part of a group, refers to a group having the formula —OR^{b} wherein R^{b} is alkyl as defined herein above. Non-limiting examples of suitable alkoxy include methoxy, ethoxy, propoxy, isopropoxy, butoxy, isobutoxy, sec-butoxy, tert-butoxy, pentyloxy and hexyloxy.

Where an alkylene group is present, connectivity to the molecular structure of which it forms part may be through a common carbon atom or different carbon atom. To illustrate this applying the asterisk nomenclature of this disclosure, a C3alkylene group may be for example *—CH₂CH₂CH₂—*, *—CH(—CH₂CH₃)—* or *—CH₂CH(—CH₃)—*.

In some embodiments, the method as disclosed herein provides that for the one or boron precursor represented by the general formula (I), the alkyl is a C1-8alkyl, and more in particular a C1-4alkyl. More in particular the alkyl is a C1, C2, C3, C4, C5, C6, C7, and/or C8 alkyl.

In some embodiments, the method as disclosed herein provides that for the one or boron precursor represented by the general formula (I), the alkenyl is a C2-8alkenyl, and more in particular a C2-4alkenyl. More in particular the alkenyl is a C2, C3, C4, C5, C6, C7, and/or C8 alkenyl.

In some embodiments, the method as disclosed herein provides that for the one or boron precursor represented by the general formula (I), the alkoxy is a C1-8alkoxy, and more in particular a C1-4alkoxy. More in particular the alkoxy is a C1, C2, C3, C4, C5, C6, C7, and/or C8 alkoxy.

In some embodiments, the present disclosure provides that R¹, R², R³, R⁴, R⁵, R⁶ are each independently selected from the group consisting of hydrogen, halogen, C1-8alkyl, C2-8alkenyl, and C1-8alkoxy.

In some embodiments, the present disclosure provides that R¹, R², R³, R⁴, R⁵, R⁶ are each independently selected from the group consisting of hydrogen, halogen, C1-4alkyl, C2-4alkenyl, and C1-4alkoxy.

In particular embodiments, the method as disclosed herein provides that the one or more boron precursor may comprise borazine or a substituted borazine.

In some embodiments the boron precursor comprises a organoborane comprising alkyl borane or alkylamino borane. The boron precursor may comprises a molecule selected from the list consisting of trimethylborane, triethylborane, 3-tris-(dimethylamino) borane, dimethylamine borane and triethylamine borane.

In some embodiments of the disclosure, the boron precursor may be pulsed into the reaction chamber for a time period from about 0.05 seconds to about 5.0 seconds, or from about 0.1 seconds to about 3 seconds, or even about 0.2 seconds to about 1.0 seconds. In addition, during the contacting of the substrate with the boron precursor, the flow rate of the boron precursor may be less than 20 slm, or less than 10 slm, or less than 7 slm, or less than 5 slm, or even less than 3 slm. In addition, during the contacting of substrate with the boron precursor, the flow rate of the boron precursor may range from about 0.05 to 10 slm, from about 0.1 to 7 slm, or from about 0.1 to about 5 slm.

In some embodiments, the excess boron precursor may be purged by stopping the flow of the vapor phase boron precursor while continuing to flow a carrier gas, a purge gas, or a gas mixture, for a sufficient time to diffuse or purge excess reactants and reactant byproducts, if any, from the reaction chamber. In some embodiments, the excess boron precursor may be purged with aid of one or more inert gases, such as nitrogen, helium or argon, that may be flowing throughout the cyclical deposition sub-steps.

In some embodiments, the boron precursor may be purged from the reaction chamber for a time period of about 0.1 seconds to about 10 seconds, or about 0.3 seconds to about 5 seconds, or even about 0.3 seconds to about 1 second. Provision and removal of the boron precursor may be considered as the first sub-step of step 104.

Upon completion of the purging the reaction chamber of excess boron precursor and any reaction by-products, the cyclical deposition stage 104 of exemplary PEALD process 100 may continue with a second sub-step comprising, contacting the substrate with a reactive species generated from a plasma produced from a nitrogen-containing gas.

In some embodiments, the nitrogen-containing gas comprises one or more of nitrogen (N₂), N₂O, NO, N₂H₂ and NH₃.

In the second sub-step, a nitrogen-containing plasma may be generated by applying RF power from about 100 W to 10000 W, or from about 10 W to about 2000 W, or from about 50 W to about 1500 W, or from about 100 W to about 1200 W. In some embodiments, the plasma may be generated in-situ, while in other embodiments, the plasma may be generated remotely. In some embodiments, a showerhead reactor may be utilized and plasma may be generated between a susceptor (on top of which the substrate is located) and a showerhead plate.

In some embodiments, the reactive species generated from the plasma may contact the substrate for a time period between about 0.1 seconds to about 20 seconds, or about 0.5 seconds to about 10 seconds, or even about 0.5 seconds to about 5 seconds. In some embodiments, the reactive species generated from the plasma may contact the substrate for a time period of between approximately 2 seconds and 10 seconds.

After a time period sufficient to completely saturate and react the previously absorbed molecular layer with the nitrogen-based plasma pulse, any excess reactant and reaction byproducts may be removed from the reaction chamber. As with the removal of the first reactant, i.e., the vapor phase boron precursor, this step may comprise stopping generation of reactive species and continuing to flow an inert gas, such as a gas comprising nitrogen, helium, and in some embodiments additionally argon. The inert gas flow may flow for a time period sufficient for excess reactive species and volatile reaction byproducts to diffuse out of and be purged from the reaction chamber. For example, the purge process may be utilized for a time period between about 0.1 seconds to about 10 seconds, or about 0.1 seconds to about 4.0 seconds, or even about 0.1 seconds to about 0.5 seconds. Together, the nitrogen-based plasma provision and removal represent a second sub-step, od step 104 in the exemplary PEALD process 100 of FIG. 1.

The method wherein the substrate is alternately and sequentially contacted with the vapor phase boron precursor and contacted with the reactive species generated from a gas comprising a nitrogen precursor may constitute a unit deposition cycle. In some embodiments of the disclosure, the exemplary PEALD process step 104 may comprise repeating the unit deposition cycle one or more times. For example, the cyclical depositions may continue whether the desired thickness is not achieved, for example, if the thickness of the deposited film is insufficient for the desired device structure, then the process of the first sub-step of contacting the substrate with the boron precursor and second sub-step of contacting the substrate with the reactant may be repeated one or more times. For example, if the thickness of the deposited material is less than desired for a particular application, then first and second sub-steps can be repeated one or more times. In some embodiments, the method comprises from at least 1 cycle to at most 500 cycles, or from at least 2 cycles to at most 450 cycles, or from at least 3 cycles to at most 400 cycles, or from at least 4 cycles to at most 350 cycles, or from at least 5 cycles to at most 300 cycles, or from at least 10 cycles to at most 290 cycles, or from at least 20 cycles to at most 280 cycles. In some embodiments, the method comprises at most 400 cycles, or at most 350 cycles, or at most 320 cycles, or at most 300 cycles, or at most 280 cycles, or at most 100 cycles, or at most 80 cycles, or at most 30 cycles, or at most 20 cycles, or at most 10 cycles, or at most 5 cycles, or at most 4 cycles, or at most 3 cycles, or at most 2 cycles, or a single cycle.

While the PEALD cycle is generally referred to herein as beginning with the boron precursor phase, it is contemplated that in other embodiments the cycle may begin with the reactive species phase. One of skill in the art will recognize that the first precursor phase generally reacts with the termination left by the last phase in the previous cycle. Thus, while no reactant may be previously absorbed on the substrate surface or present in the reaction chamber if the reactive species is the first phase in the PEALD cycle, in subsequent cycles the reactive species phase will effectively follow the boron precursor phase. In some embodiments, one or more different PEALD cycles are provided in the deposition process.

In some embodiments, the deposited first material comprises boron nitride. In some embodiments of the disclosure, the boron nitride may be deposited on a three-dimensional structure, e.g., a non-planar substrate comprising high aspect ratio features. In some embodiments, the step coverage of the boron nitride film may be equal to or greater than about 50%, or greater than about 60%, or greater than about 70%, or greater than about 80%, or greater than about 90%, or greater than about 95%, or greater than about 98%, or greater than about 99%, or greater in structures having aspect ratios (height/width) of more than about 2, more than about 5, more than about 10, more than about 25, more than about 50, or even more than about 100.

In some embodiments, the boron nitride is deposited on a substrate comprising a gap. In some embodiments, the substrate comprises silicon oxide material. In some embodiments, the substrate comprises silicon nitride, silicide, amorphous silicon or metal. The boron nitride is deposited conformally into the gap to fill the gap at least partially.

Next, part of the first material is etched in step 105 of method 100. The etching is selective in step 105. In other words, the etchant only removes the wanted first material, such as boron nitride, but does not etch the substrate under the first material, such as silicon oxide. The selective etch step 105 can be performed by, for example, providing an etching reactant and providing an etch plasma power to form activated species from etching reactant.

In step 105, only a part of the first material is removed from the surface of the substrate. In some embodiments, the substrate comprises a gap and the first material was deposited conformally to fill the gap at least partially in step 104. In these embodiments, the first material is removed near the top of the gap, still leaving the gap at least partially filled with the first material.

In step 105, the plasma may be provided as a pulsed plasma. In accordance with examples, a plasma pulse period is between about 0.01 and 0.2 msec. The plasma pulse period may add up to a total plasma on time of from about 1 seconds to about 20 (e.g., 10) seconds or about 0.3 seconds to about 10 (e.g., 5) seconds or about 8 seconds to about 12 seconds or about 3 seconds to about 7 seconds. In addition, during the contacting of the substrate with the etching reactant, the flow rate of the etching reactant may be less than 20 slm, or less than 10 slm, or less than 7 slm, or less than 5 slm, or even less than 3 slm. In addition, during the contacting of substrate with the etching reactant, the flow rate of the etching reactant may range from about 0.05 to 10 slm, from about 0.1 to 7 slm, or from about 0.1 to about 5 slm.

In accordance with additional examples, a plasma power on-time duty cycle is greater than 0 and less than 99% or between about 5 and 95%. A plasma power during step 105 can range from about 100 W to about 10000 W or about 150 W to about 1000 W or about 100 W to about 1000 W, or about 100 W to about 400 W.

A frequency of the pulsed plasma power can vary depending on the plasma source between about 400 kHz to 100 GHz. The plasma source is step 104 is selected from at least one of high-density plasma, microwave plasma or inductively coupled plasma. In inductively coupled plasma the RF is between 25 and 45 MHz, such as 27 to 41 MHz. In high-density plasma the RF is up to 100 MHz, such 50 to 90 MHz, for example 55 to 70 MHz. In microwave plasma the microwave radiation is applied at a RF of 0.3-100 GHz, for example 0.5-100 GHz, such as 1-20 GHz, or 2-5 GHz. In some embodiments, the plasma source step 104 is selected from two of high-density plasma, microwave plasma or inductively coupled plasma.

In embodiments using high-density plasma, the thermal conductivity of the deposited film may increase. The high-density plasma changes the crystallinity of the film as the radicals react with it. In some embodiments, the thermal conductivity of the films deposited at least partially by using high-density plasma is about two times higher than the films deposited with other types of plasma.

In some embodiments, the etchant reactant comprises fluorine. In some embodiments, the etchant reactant is selected from the list consisting of NF₃, CF₄, C2F₆, SF₆, NH₂F, C3F₈, F₂, XeF₂, HF, CHF₃, CH₃F, CH₂F₂, C4F₈, C4F₆, Cl₂, SiCl₄, BCl₃, C4F₆, NH₃, N₂H₂ and any combinations thereof. When the etchant reactant is treated with the plasma mentioned above, the etchant reactant breaks down into reactive species, such as more reactive ions and radicals. These reactive species are then capable of etching the first material deposited on the substrate. The plasma enhances the etching process by providing the necessary energy to activate the etchant reactant, thereby facilitating the removal of the desired material from the substrate surface. This process is particularly useful for achieving selective etching, where only specific materials are targeted for removal without affecting the underlying layers.

In some embodiments, the etching process is spontaneous etching. In spontaneous etching, the reactive species generated from the etchant reactant gas are sufficiently reactive to interact with the first material on the substrate surface, leading to its removal. This type of etching relies on the inherent chemical reactivity of the etchant species with the first material to be etched. The amount of first material etched depends on the amount of etchant reactant provided into the reaction chamber. The more etchant reactant provided into the reaction chamber, in other words, the longer the etchant reactant pulse time, the more the first material is etched.

Once the required amount of first material is etched, the method 100 moves to step 106 to deposit a first material. In step 106 the first material is deposited similarly to step 104. In some embodiments, instead of depositing a first material, a third material is deposited in step 106. The third material may comprise silicon nitride. Below is described the embodiments in which a third material is deposited.

Step 106 may be divided into two sub-steps, a first sub-step of providing a silicon precursor into the reaction chamber and a second sub-step of contacting the substrate with a reactive species generated from a plasma produced from a nitrogen-containing gas. When the step 104 includes a cyclical process, the first and second sub-steps can be performed sequentially with an intervening purge step between them. When the step 104 includes a CVD process, the first and second sub-steps can overlap. In the first sub-set, a silicon precursor is provided into the reaction chamber in vapor phase. In the case of cyclical deposition, the silicon precursor can be pulsed to the reaction chamber. In accordance with some embodiments, the silicon precursor may be supplied to the reaction chamber with some carrier gas flow. In some embodiments, the silicon precursor may comprise a volatile silicon species that is reactive with the surface of the substrate. The silicon precursor pulse may self-saturate the substrate surface such that excess constituents of the silicon precursor pulse do not further react with the molecular layer formed by this process.

The silicon precursor pulse is preferably supplied as a vapor phase reactant. The silicon precursor gas may be considered “volatile” for the purposes of the present disclosure if the species exhibits sufficient vapor pressure under the process conditions to transport species to the substrate surface in sufficient concentration to saturate the exposed surfaces.

In some embodiments, the vapor phase silicon precursor comprises silane, halogensilane or organosilane. In some embodiments, the silicon precursor comprises halogensilane and the halogensilane comprises one or more of dichlorosilane, diiodosilane, hexachlorodisilane, octachlorotrisilane, dibromosilane, tribromosilane, trichlorosilane (HSiCl₃), chlorosilane (H₃SiCl), silicon tetrachloride (SiCl₄), bromosilane (H₃SiBr), triiodosilane (HSiI₃), iodosilane (H₃SiI), diiiodosilane (H₂Si₂I₄), H₄Si₂I₂, and H₅Si₂I.

In some embodiments, the silicon precursor comprises organosilane, and the organosilna comprises one or more of aminosilnae and heterosilane.

In some embodiments, the silicon precursor is selected from the list consisting of tris(dimethylamino) silane, bis(tert-butylamino) silane, di(sec-butylamino) silane, trisilylamine, neopentasilane, bis(dimethylamino) silane, (dimethylamino) silane (DMAS), bis(diethylamino) silane (BDEAS), bis(ethylmethylamino) silane (BEMAS), tetrakis(dimethylamino) silane (TKDMAS), trimethylsilane (SiH(CH₃)₃), tetramethylsilane (Si(CH₃)₄), silane, tetra(ethoxy) silane (TEOS, Si(OC₂H₅)₄), tris(tert-butoxy) silanol (TBOS), tris(tert-pentoxy) silanol (TPSOL), and dimethyldichlorosilane (Si(OC₂H₅)₄, Si(CH₃)₂(OCH₃)₂).

In some embodiments of the disclosure, the silicon precursor may be pulsed into the reaction chamber for a time period from about 0.05 seconds to about 5.0 seconds, or from about 0.1 seconds to about 3 seconds, or even about 0.2 seconds to about 1.0 seconds. In addition, during the contacting of the substrate with the silicon precursor, the flow rate of the silicon precursor may be less than 20 slm, or less than 10 slm, or less than 7 slm, or less than 5 slm, or even less than 3 slm. In addition, during the contacting of substrate with the silicon precursor, the flow rate of the silicon precursor may range from about 0.05 to 10 slm, from about 0.1 to 7 slm, or from about 0.1 to about 5 slm.

In some embodiments, the excess silicon precursor may be purged by stopping the flow of the vapor phase silicon precursor while continuing to flow a carrier gas, a purge gas, or a gas mixture, for a sufficient time to diffuse or purge excess reactants and reactant byproducts, if any, from the reaction chamber. In some embodiments, the excess silicon precursor may be purged with aid of one or more inert gases, such as nitrogen, helium or argon, that may be flowing throughout the cyclical deposition sub-steps.

In some embodiments, the silicon precursor may be purged from the reaction chamber for a time period of about 0.1 seconds to about 10 seconds, or about 0.3 seconds to about 5 seconds, or even about 0.3 seconds to about 1 second. Provision and removal of the silicon precursor may be considered as the first sub-step of step 106.

Upon completion of the purging the reaction chamber of excess silicon precursor and any reaction by-products, the cyclical deposition stage 106 of exemplary PEALD process 100 may continue with a second sub-step comprising, contacting the substrate with a reactive species generated from a plasma produced from a nitrogen-containing gas.

In some embodiments, the nitrogen-containing gas comprises one or more of nitrogen (N₂), N₂O and NO.

In the second sub-step, a nitrogen-containing plasma may be generated by applying RF power from about 10 W to about 2000 W, or from about 50 W to about 1500 W, or from about 100 W to about 1200 W. In some embodiments, the plasma may be generated in-situ, while in other embodiments, the plasma may be generated remotely. In some embodiments, a showerhead reactor may be utilized and plasma may be generated between a susceptor (on top of which the substrate is located) and a showerhead plate.

In some embodiments, the reactive species generated from the plasma may contact the substrate for a time period between about 0.1 seconds to about 20 seconds, or about 0.5 seconds to about 10 seconds, or even about 0.5 seconds to about 5 seconds. In some embodiments, the reactive species generated from the plasma may contact the substrate for a time period of between approximately 2 seconds and 10 seconds.

After a time period sufficient to completely saturate and react the previously absorbed molecular layer with the nitrogen-based plasma pulse, any excess reactant and reaction byproducts may be removed from the reaction chamber. As with the removal of the first reactant, i.e., the vapor phase silicon precursor, this step may comprise stopping generation of reactive species and continuing to flow an inert gas, such as a gas comprising nitrogen, helium, and in some embodiments additionally argon. The inert gas flow may flow for a time period sufficient for excess reactive species and volatile reaction byproducts to diffuse out of and be purged from the reaction chamber. For example, the purge process may be utilized for a time period between about 0.1 seconds to about 10 seconds, or about 0.1 seconds to about 4.0 seconds, or even about 0.1 seconds to about 0.5 seconds. Together, the nitrogen-based plasma provision and removal represent a second sub-step, od step 106 in the exemplary PEALD process 100 of FIG. 1.

The method wherein the substrate is alternately and sequentially contacted with the vapor phase silicon precursor and contacted with the reactive species generated from a gas comprising a nitrogen precursor may constitute a unit deposition cycle. In some embodiments of the disclosure, the exemplary PEALD process step 106 may comprise repeating the unit deposition cycle one or more times. For example, the cyclical depositions may continue whether the desired thickness is not achieved, for example, if the thickness of the deposited film is insufficient for the desired device structure, then the process of the first sub-step of contacting the substrate with the silicon precursor and second sub-step of contacting the substrate with the reactant may be repeated one or more times. For example, if the thickness of the deposited material is less than desired for a particular application, then first and second sub-steps can be repeated one or more times. In some embodiments, the method comprises from at least 1 cycle to at most 1000 cycles, or from at least 2 cycles to at most 850 cycles, or from at least 3 cycles to at most 800 cycles, or from at least 4 cycles to at most 750 cycles, or from at least 5 cycles to at most 700 cycles, or from at least 10 cycles to at most 590 cycles, or from at least 20 cycles to at most 480 cycles. In some embodiments, the method comprises at most 1500 cycles, or at most 1000 cycles, or at most 800 cycles, or at most 320 cycles, or at most 300 cycles, or at most 280 cycles, or at most 100 cycles, or at most 80 cycles, or at most 30 cycles, or at most 20 cycles, or at most 10 cycles, or at most 5 cycles, or at most 4 cycles, or at most 3 cycles, or at most 2 cycles, or a single cycle.

While the PEALD cycle is generally referred to herein as beginning with the silicon precursor phase, it is contemplated that in other embodiments the cycle may begin with the reactive species phase. One of skill in the art will recognize that the first precursor phase generally reacts with the termination left by the last phase in the previous cycle. Thus, while no reactant may be previously absorbed on the substrate surface or present in the reaction chamber if the reactive species is the first phase in the PEALD cycle, in subsequent cycles the reactive species phase will effectively follow the silicon precursor phase. In some embodiments, one or more different PEALD cycles are provided in the deposition process.

In the embodiments relating to filling a gap, in step 106 the gap is filled fully. Once the first or third material is deposited in step 106, the method 100 ends 107.

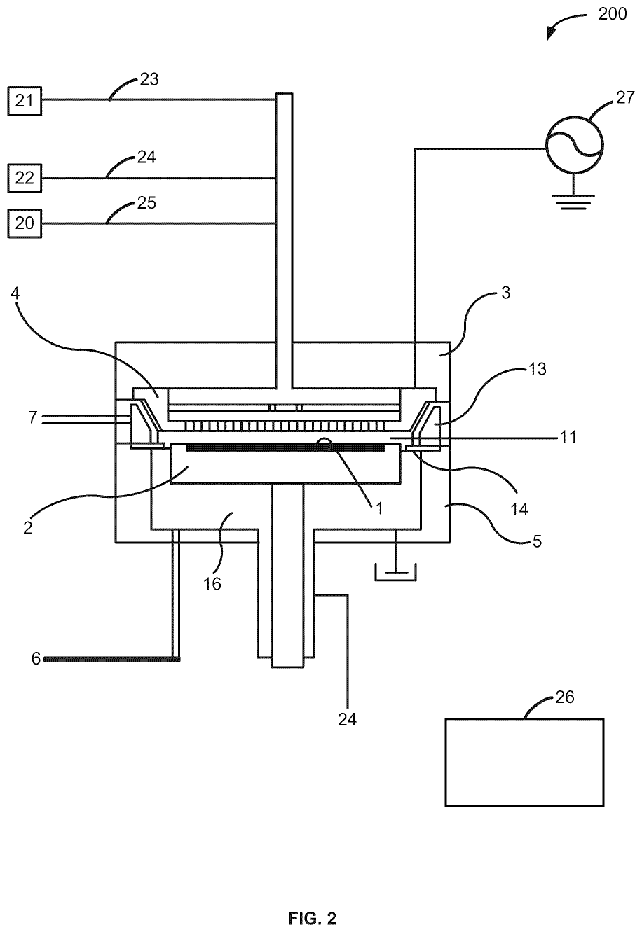

Turning now to FIG. 2, a reactor system 200 is illustrated in accordance with exemplary embodiments of the disclosure. Reactor system 200 can be used to perform one or more steps or sub steps as described herein and/or to form one or more structures or portions thereof as described herein.

Reactor system 200 includes a pair of electrically conductive flat-plate electrodes 4, 2 in parallel and facing each other in the interior 11 (reaction zone) of a reaction chamber 3. A plasma can be excited within reaction chamber 3 by applying, for example, HRF power (e.g., 100 kHz, 13.56 MHz, 27 MHz, 2.45 GHz, or any values therebetween) from power source 27 to one electrode (e.g., electrode 4) and electrically grounding the other electrode (e.g., electrode 2). A temperature regulator is provided in a lower stage 2 (the lower electrode), and a temperature of a substrate 1 placed thereon can be kept at a desired temperature, such as the substrate temperatures noted above. Electrode 4 can serve as a gas distribution device, such as a shower plate or showerhead. Precursor gas, nitrogen reactant gases, etching reactant gas, and dilution/carrier gas, if any, or the like can be introduced into reaction chamber 3 using one or more of a gas line 23, a gas line 24, and a gas line 25, from sources 21, 22, and 20, respectively, and through the shower plate 4. Although illustrated with four gas lines 23, 24, 25, and 26, reactor system 200 can include any suitable number of gas lines. By way of examples, source 21 can correspond to a boron precursor source, source 22 can correspond to a nitrogen reactant source, and source 20 can correspond to an etching reactant source.

In reaction chamber 3, a circular duct 13 with an exhaust line 7 is provided, through which gas in the interior 11 of the reaction chamber 3 can be exhausted. Additionally, a transfer chamber 5, disposed below the reaction chamber 3, is provided with a seal gas line 24 to introduce seal gas into the interior 11 of the reaction chamber 3 via the interior 16 (transfer zone) of the transfer chamber 5, wherein a separation plate 14 for separating the reaction zone and the transfer zone is provided (a gate valve through which a substrate is transferred into or from the transfer chamber 5 is omitted from this figure). The transfer chamber is also provided with an exhaust line 6. In some embodiments, the deposition and/or etching steps are performed in the same reaction space, so that two or more (e.g., all) of the steps can continuously be conducted without exposing the substrate to air or other oxygen-containing atmosphere.

In some embodiments, continuous flow of a carrier gas to reaction chamber 3 can be accomplished using a flow-pass system (FPS), wherein a carrier gas line is provided with a detour line having a precursor reservoir (bottle), and the main line and the detour line are switched, wherein when only a carrier gas is intended to be fed to a reaction chamber, the detour line is closed, whereas when both the carrier gas and a precursor gas are intended to be fed to the reaction chamber, the main line is closed and the carrier gas flows through the detour line and flows out from the bottle together with the precursor gas. In this way, the carrier gas can continuously flow into the reaction chamber, and can carry the precursor gas in pulses by switching between the main line and the detour line, without substantially fluctuating pressure of the reaction chamber.

Reactor system 200 can include one or more controller(s) 26 programmed or otherwise configured to cause one or more method steps as described herein to be conducted. Controller(s) 26 are coupled with the various power sources, heating systems, pumps, robotics and gas flow controllers, or valves of the reactor, as will be appreciated by the skilled artisan. By way of example, controller 26 can be configured to control gas flow of a silicon precursor, a nitrogen reactant, and an etching reactant into at least one of one or more reaction chambers.

In some embodiments, the reactor system 200 can include a remote plasma unit, a microwave plasma unit or a high-density plasma unit (not shown). At least one of these plasma units can be activated when the etching reactant is provided into the reaction chamber to provide reactive species. In these embodiments, both the deposition step as shown in FIG. 1 method 100 steps 104 and 106 can be performed in the same reactor system as the etching step 105.

In some embodiments, a dual chamber reactor (two sections or compartments for processing substrates disposed close to each other) can be used, wherein a reactant gas and a noble gas can be supplied through a shared line, whereas a precursor gas is supplied through unshared lines.

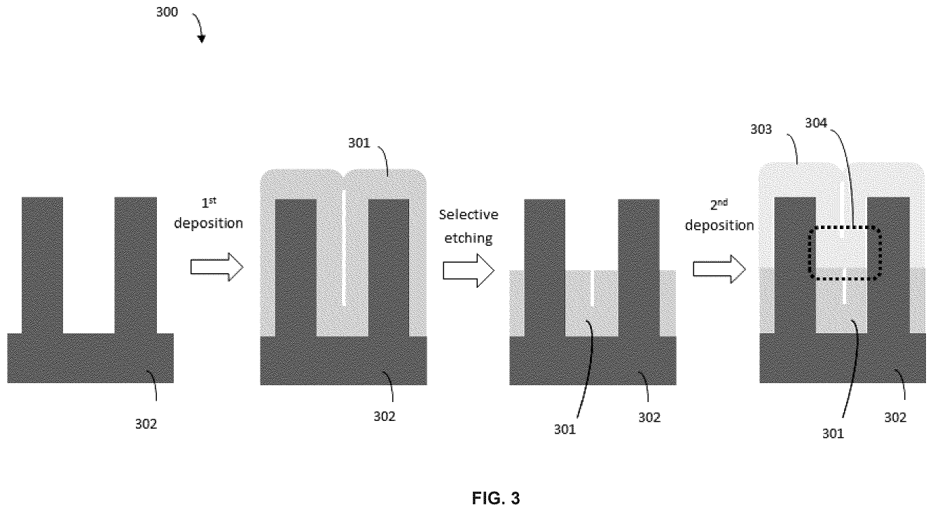

Now turning to FIG. 3, a method illustrated a method 300 in accordance with exemplary embodiments of the disclosure. The method 300 relates to filling a gap on a substrate. The substrate 302 comprises the second material, such as silicon oxide, and comprises at least one gap as shown in FIG. 3. The gap comprises a proximal surface, sidewalls and a distal surface. The proximal surface is the surface at the top of the gap and the distal surface is the surface at the bottom of the gap.

First, a first deposition is performed. The deposition can be similar to the step 104 described in accordance with FIG. 1. The first deposition conformally deposits a first material, such as boron nitride, 301 onto the surface of the substrate 302 to fill the gap. The first material is deposited on the proximal, and distal surfaces as well as the sidewalls. The thickness of the deposited first material is about the same on each of the proximal, and distal surfaces and sidewalls. In some embodiments, the first deposition leaves a seam or a void in the gap.

Second, part of the first material is selectively etched from the gap. The etching can be similar to the step 105 described in accordance with FIG. 1. The selective etching etches a part of the deposited first material 301 from the gap, but does not etch, or substantially does not etch the substrate 302 material. The etching is performed in-situ in the same reaction chamber as the first deposition and the second deposition steps.

Third, once the wanted amount of first material is etched, a second deposition is performed. The second deposition can be similar to the step 106 described in accordance with FIG. 1. The second deposition conformally deposits a first material, such as boron nitride, or a third material, such as silicon nitride, 303 onto the underlaying first material 301 and the parts of the surface of the substrate 302 that are not covered by first material 301, to fill the gap. The first or third material 303 is deposited on the proximal, and distal surfaces as well as the sidewalls. The thickness of the deposited first or third material is about the same on each of the proximal, and distal surfaces and sidewalls. In some embodiments, the second deposition leaves a seam or a void in the gap. As the first or third material 303 is conformally deposited onto the seam or void of the first deposition, a seam-stop layer 304 is formed into the gap. The seam-stop layer 304 may improve the gapfill quality so that it can withstand subsequent process flow steps (not described herein).

In some embodiments (not shown), the first or third material 303 is finally etched back so that it does not substantially cover the proximal surface and the gap is only filled to the level of the proximal surface.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method for forming a structure, comprising
providing a substrate comprising a deposited first material into the reaction chamber; and
providing a reactive species generated from a plasma produced from an etching reactant gas into the reaction chamber to etch the first material,
wherein the plasma is pulsed plasma, and
wherein the plasma is selected from at least one of high-density plasma, microwave plasma and inductively coupled plasma.

2. The method according to claim 1, wherein the etching is spontaneous etching.

3. The method according to claim 1, wherein the etching reactant is selected from the list consisting of NF₃, CF₄, C₂F₆, SF₆, NH₂F, C₃F₈, and F₂, XeF₂, HF, CHF₃, CH₃F, CH₂F₂, C₄F₈, C₄F₆, Cl₂, SiCl₄, BCl₃, C₄F₆, NH₃, N₂H₂ and any combinations thereof.

4. A method for forming a structure, comprising
a step of providing a substrate into a reaction chamber, the substrate comprising a second material;
a step of conformally depositing first material onto the substrate;
a step of selectively etching at least part of the first material; and
a step of conformally depositing third or first material onto the substrate,
wherein all the said steps are performed in the same reaction chamber.

5. The method according to claim 4, wherein the substrate comprises at least one gap having a proximal surface, sidewalls and a distal surface.

6. The method according to claim 4, wherein the second material is conformally deposited into the at least one gap to fill the gap, so that the deposited first material covers the proximal surface, the sidewalls and the distal surface.

7. The method according to claim 5, wherein during the step of selectively etching at least part of the first material, the first material is etched so that the gap is partially filled.

8. The method according to claim 5, further comprising etching the third or first material so that substantially no material covers the proximal surface.

9. The method according to claim 4, wherein the second material comprises silicon oxide.

10. The method according to claim 4, wherein the first material comprises boron nitride.

11. The method according to claim 4, wherein the third material comprises silicon nitride.

12. The method according to claim 4, wherein the step of selectively etching comprises removing the first material, and not removing or substantially not removing any of the second material.

13. The method according to claim 4, wherein the step of selectively etching is performed by:
providing a substrate comprising a deposited first material into the reaction chamber; and
providing a reactive species generated from a plasma produced from an etching reactant gas into the reaction chamber to etch the first material,
wherein the plasma is pulsed plasma, and
wherein the plasma is selected from at least one of high-density plasma, microwave plasma and inductively coupled plasma.

14. The method according to claim 4, wherein the first material is conformally deposited by executing at least one deposition cycle, wherein the at least one deposition cycle comprises
providing a boron precursor into the reaction chamber in vapor phase; and
providing a reactive species generated from a plasma produced from a nitrogen-containing gas into the reaction chamber.

15. The method according to claim 14, wherein the boron precursor comprises one or more of boron halide, borane, borazine and organoborane.

16. The method according to claim 14, wherein the boron precursor comprises boron halide selected from list consisting of boron triiodide, boron tribromide, boron trichloride, diboron tetrachloride, boron monofluoride, boron trifluoride and diboron tetrafluoride.

17. The method according to claim 14, wherein the boron precursor comprises borane selected from borane, diborane, tetraborane, pentaborane, decaborane and borane-ammonia complex.

18. The method according to claim 14, wherein the boron precursor comprises borazine represented by the following formula (I) 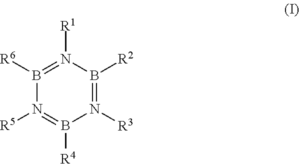
wherein R¹, R², R³, R⁴, R⁵, R⁶ are each independently selected from the group consisting of hydrogen, halogen, alkyl, alkenyl, and alkoxy.

19. The method according to claim 14, wherein the boron precursor comprises organoborane selected from the list consisting of trimethylborane triethylborane, 3-tris-(dimethylamino) borane, dimethylamine borane, triethylamine borane.

20. The method according to claim 14, wherein the nitrogen-containing gas comprises one or more of nitrogen (N₂), N₂O, and NO.

21. A system for depositing a material on a surface of a substrate, the system comprising;
a rection chamber for accommodating a substrate comprising a gap and a second material;
a silicon precursor source in fluid communication via a first valve with the reaction chamber;
a nitrogen reactant source in fluid communication via a second valve with the reaction chamber;
an etching reactant source in fluid communication via a third valve with the reaction chamber; and
a controller operably connected to the first valve, the second valve and the third valve, and configured and programmed to control:
supplying a boron precursor into the reaction chamber;
supplying a nitrogen reactant into the reaction chamber;
supplying an etchant into the reaction chamber; and
depositing a material on the surface of the substrate with the method according to claim 4.
